(19) United States
(12) Patent Application Publication
(10) Pub. No.: US 2026/0293569 A1
(43) Pub. Date: Sep. 24, 2026

(54) SUBSTRATE PROCESSING APPARATUS

(71) Applicant: SCREEN Holdings Co., Ltd., Kyoto (JP)

(72) Inventor: Fumihiko IKEDA, Kyoto-shi (JP)

(21) Appl. No.: 19/420,905

(22) Filed: Dec. 16, 2025

(30) Foreign Application Priority Data
Mar. 21, 2025 (JP) 2025-047354

(51) Int. Cl. H10P 72/00

(52) U.S. Cl. CPC H10P 72/0404

(57) ABSTRACT

A substrate processing apparatus includes: a spinning base that hold a substrate; a spinning shaft mounted on the spinning base; a spinning motor that rotates the spinning shaft about a rotary axis; a nozzle that supplies a processing liquid to the substrate; a lower cup arranged around and below the spinning base; a middle cup located below the spinning base and above a bottom wall part of the lower cup; and a gas flow distribution plate standing upward from the bottom wall part of the lower cup toward the middle cup. The gas flow distribution plate includes a plurality of opening parts. The lower cup includes an exhaust port arranged on an internal side of a radial direction with respect to the gas flow distribution plate, and a drainage port arranged on an external side of the radial direction with respect to the gas flow distribution plate.

### RELATED APPLICATIONS

This application claims the benefit of Japanese Application No. 2025-047354, filed on Mar. 21, 2025, the disclosure of which is incorporated by reference herein.

### BACKGROUND OF THE INVENTION

### Field of the Invention

A subject matter disclosed in this specification relates to a substrate processing apparatus.

### Description of the Background Art

During a course of manufacturing a liquid crystal display device or a semiconductor device, a process of forming a circuit pattern on a substrate such as a glass substrate or a semiconductor wafer is performed. More specifically, the process performed on the substrate is a developing process, an etching process, or a resist stripping process, for example. These processes are carried outby supplying a developing, an etching liquid, a stripping liquid or the like to the substrate, followed by a cleaning step in which a cleaning liquid such as pure water is supplied. In recent years, these processes are further performed on a substrate for panel level package (PLP) that is a so-called substrate for semiconductor package.

As an example, Japanese Patent Application Laid-Open No. 2010-010555 discloses a substrate processing apparatus for performing a developing process. This substrate processing apparatus includes a spinning chuck that rotates a substrate while holding the substrate in a horizontal posture, a nozzle for supplying a developing liquid onto the substrate, and a cup that surrounds the substrate held by the spinning chuck. During the developing process, the developing liquid is supplied onto the substrate from the nozzle while the substrate is rotated by the spinning chuck. The developing liquid supplied onto the substrate during the developing process is scattered around the substrate. Much of the developing liquid scattered around the substrate is received by a cup.

The developing liquid or the cleaning liquid scattered from the substrate is diffused into the body of the cup to generate mist. According to Japanese Patent Application Laid-Open No. 2010-010555, in order to collect the mist of the processing liquid, a gas-liquid separator is provided in a drainage pipe communicably provided at a bottom of the cup body. After the processing liquid drops onto the bottom of the cup body, the processing liquid flows into the gas-liquid separator via the drainage pipe. Then, the processing liquid is separated into gas and liquid by the gas-liquid separator, the gas is discharged by an exhaust blower, and the liquid is collected appropriately.

### SUMMARY OF THE INVENTION

### Technical Problem

However, providing the gas-liquid separator in the drainage pipe like in the conventional technique requires an additional installation space to be ensured within a limited apparatus size, imposing difficulty in size reduction of the apparatus. Furthermore, locating the gas-liquid separator below the cup increases the height of a processing position for the substrate. This further increases the height of a maintenance space and increases the height of a pass line at which the substrate is loaded into and unloaded from the substrate processing apparatus. Therefore, there is a need for space-saving for gas-liquid separation.

The present invention is aims to provide a technique for effectively performing gas-liquid separation in a reduced space.

### Solution to Problem

To solve the above problem, a first aspect is intended for a substrate processing apparatus comprising: a chuck that holds a substrate; a spinning shaft mounted on the chuck; a motor that rotates the spinning shaft about a rotary axis extending in a vertical direction; a nozzle that supplies a processing liquid to the substrate held by the chuck; a lower cup having a circular cylindrical shape with a closed bottom arranged around and below the chuck; a middle cup having an annular shape located below the chuck and above a bottom of the lower cup; and a gas flow distribution member having a cylindrical shape standing upward from the bottom of the lower cup toward the middle cup. The gas flow distribution member includes at least one opening part. The lower cup includes an exhaust port arranged on an internal side of a radial direction with respect to the gas flow distribution member, and a drainage port arranged on an external side of the radial direction with respect to the gas flow distribution member.

According to the first aspect, it is possible to make gas-liquid separation using the gas flow distribution member provided with the opening part. This makes a gas-liquid separator omissible, so that gas-liquid separation can be made in a reduced space.

According to a second aspect, in the substrate processing apparatus according to the first aspect, the gas flow distribution member includes a plurality of the opening parts arranged in a peripheral direction.

In the substrate processing apparatus according to the second aspect, providing the plurality of opening parts makes it possible to avoid exhaust concentration in the vicinity of the exhaust port.

According to a third aspect, in the substrate processing apparatus according to the first or second aspect, a clearance is formed between a lower end of the middle cup and a bottom surface of the lower cup, and the opening part is located above the clearance.

In the substrate processing apparatus according to the third aspect, after mist containing liquid passes through the clearance, it is possible to reduce the occurrence of passage of the liquid through the opening part.

According to a fourth aspect, in the substrate processing apparatus according to any one of the first to third aspects, the middle cup includes a part tilting upward toward an internal side of the radial direction.

According to a fifth aspect, the substrate processing apparatus according to any one of the first to fourth aspects further comprises: a base mounted with the motor and supporting the lower cup; a drive pulley mounted on a drive shaft of the motor; a driven pulley mounted on the spinning shaft; and a drive belt stretched over the drive pulley and the driven pulley.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing the configuration of a substrate processing system including a substrate processing apparatus according to a preferred embodiment;

FIG. 2 is a schematic sectional view showing the configuration of the substrate processing apparatus according to the preferred embodiment;

FIG. 3 shows a lower cup and a gas flow distribution plate in FIG. 2;

FIG. 4 is a control block diagram of the substrate processing apparatus; and

FIG. 5 is a schematic sectional view showing the configuration of a substrate processing apparatus according to a modification.

### DESCRIPTION OF THE PREFERRED EMBODIMENTS

A preferred embodiment of the present invention will be described below by referring to the accompanying drawings. To facilitate understanding, the dimension of each part or the number of such parts may be exaggerated or simplified in the drawings.

### 1. Preferred Embodiment

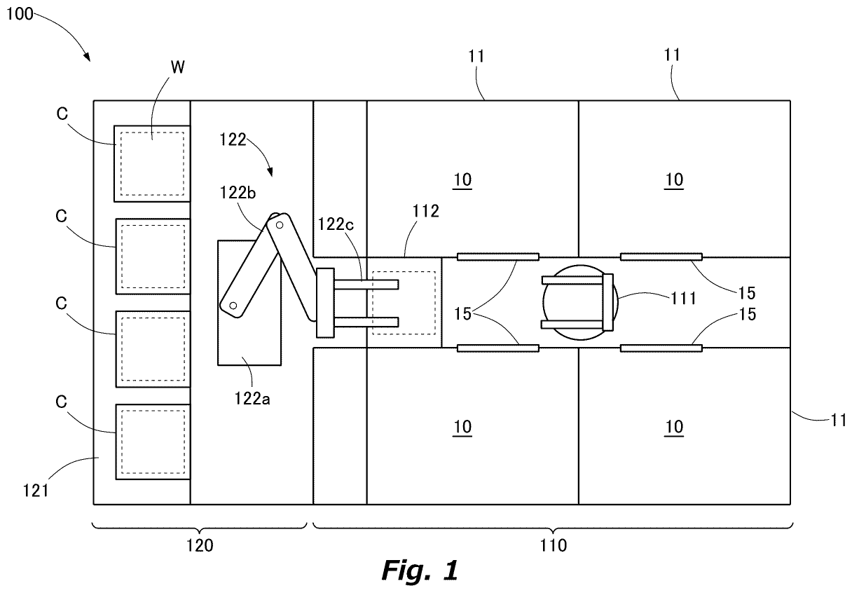

FIG. 1 is a plan view schematically showing the configuration of a substrate processing system including a substrate processing apparatus 10 according to a preferred embodiment. A substrate processing system 100 is installed in a clean room, for example. The substrate processing system 100 includes a plurality of the substrate processing apparatuses 10. Each substrate processing apparatus 10 processes one substrates W at a time. Each substrate processing apparatus 10 receives a rectangular substrate W (e.g., for PLP) and performs a developing process by supplying a developing liquid to its upper surface. In the example in FIG. 1, four substrate processing apparatuses 10 are arranged in the same horizontal plane.

The substrate processing system 100 includes a substrate processing area 110 for processing the rectangular substrate W. An indexer unit 120 is arranged at a position next to the substrate processing area 110. The indexer unit 120 is an equipment front end module (EFEM), for example, and includes a container holder 121 holding containers C in which the substrates W are housed. The containers C are each capable of housing a plurality of the substrates W in an airtight state. Each container C houses a plurality of the substrates W in a substantially horizontal posture. The containers C include a front opening unified pod (FOUP), a standard mechanical interface (SMIF) pod, and an open cassette (OC), for example. The indexer unit 120 includes an indexer robot 122. The indexer robot 122 accesses the container C held by the container holder 121, and receives unprocessed substrate W from the container C and stores processed substrate W into the container C.

The indexer robot 122 includes a base part 122a fixed to an apparatus housing, a multi-joint arm 122b, and a hand 122c. The multi-joint arm 122b is provided rotatable about a vertical axis relative to the base part 122a. The hand 122c is mounted on a tip of the multi-joint arm 122b.

The substrate processing system 100 includes a substrate transport robot 111 and a mount 112. The substrate transport robot 111 is arranged at a substantially central position in the substrate processing area 110. The mount 112 is arranged in the substrate processing area 110. The mount 112 is a table for receiving the substrate W from the indexer robot 122.

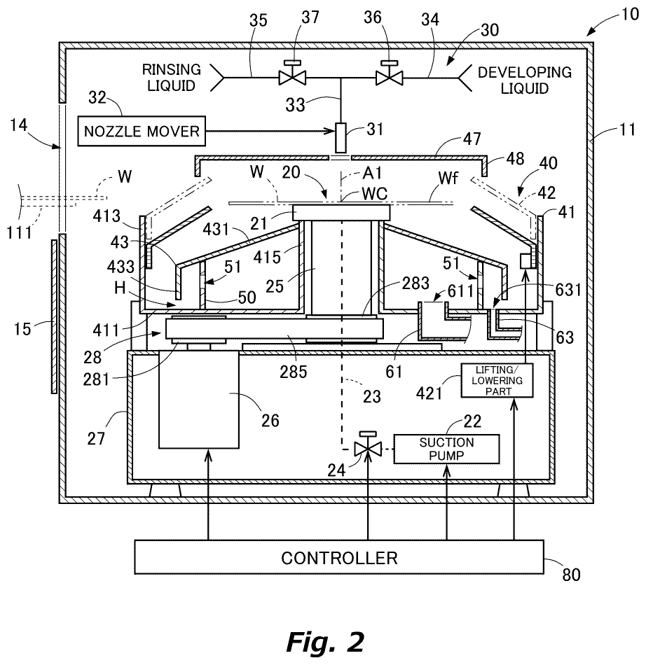

FIG. 2 is a schematic sectional view showing the configuration of the substrate processing apparatus 10 according to the preferred embodiment. The substrate processing apparatus 10 processes the substrate W by supplying a processing liquid (a developing liquid or a rinsing liquid) to an upper surface Wf of the substrate W while rotating the substrate W about a rotary axis A1 extending in a vertical direction. In the following description, a direction of the rotation about the rotary axis A1 will be referred to as a “peripheral direction.” A direction in which a straight line perpendicular to the rotary axis A1 extends will be referred to as a “radial direction.” Regarding the radial direction, one side of the radial direction toward the rotary axis A1 will be defined as an internal side of the radial direction, and the other side of the radial direction away from the rotary axis A1 will be defined as an external side of the radial direction.

The substrate processing apparatus 10 includes a box-shape chamber 11. The chamber 11 has an loading/unloading port 14 and a shutter 15. The loading/unloading port 14 and the shutter 15 are provided at a side wall of the chamber 11. The loading/unloading port 14 is a through hole for causing the substrate W to pass therethrough. The shutter 15 controls opening and closing of the loading/unloading port 14. As shown in FIG. 2, when the shutter 15 is opened, the substrate W is loaded into the chamber 11 via the loading/unloading port 14.

The substrate processing apparatus 10 includes a spinning chuck unit 20. The spinning chuck unit 20 includes a spinning base 21, a suction pump 22, a suction pipe 23 a suction valve 24, a spinning shaft 25, a spinning motor 26, a motor housing 27, and a power transmission mechanism 28. If factory utilities are used as a suction source (negative pressure source), the suction pump 22 need not to be provided within the substrate processing apparatus 10.

The spinning base 21 (chuck) is to rotate the substrate W while holding the substrate W horizontally. The spinning base 21 has an upper surface provided with a plurality of suction grooves formed in a radial pattern. A suction hole communicating with these suction grooves is provided at the center of the upper surface of the spinning base 21. Two or more suction holes may be provided in the suction grooves. The suction hole is connected to the suction pump 22 (or suction source) via the suction pipe 23. The suction valve 24 is interposed in the suction pipe 23. The suction valve 24 opens and closes a flow path in the suction pipe 23 on the basis of a command from a controller 80. The suction valve 24 is an electromagnetic valve, for example.

The spinning shaft 25 has a circular cylindrical shape extending in the vertical direction. The spinning shaft 25 is coupled to a central part of a lower surface of the spinning base 21. The spinning motor 26 rotates the spinning base 21 and the spinning shaft 25 about the rotary axis A1 on the basis of a command from the controller 80. The spinning motor 26 is separated toward the external side of the radial direction from the spinning shaft 25.

The motor housing 27 houses the spinning motor 26. The spinning motor 26 has an output axis (shaft) exposed upward from the motor housing 27. A lower cup 41 is fixed to an upper surface of the motor housing 27. The motor housing 27 is a base supporting the lower cup 41.

The power transmission mechanism 28 includes a drive pulley 281, a driven pulley 283, and a drive belt 285. The drive pulley 281 is integrated with the output axis of the spinning motor 26. The driven pulley 283 is fixed to a lower end portion of the spinning shaft 25. The drive belt 285 is an endless belt stretched over the drive pulley 281 and the driven pulley 283.

The rotation of the output axis of the spinning motor 26 is transmitted to the drive pulley 281. The drive pulley 281 rotates the driven pulley 283 via the drive belt 285. By doing so, the spinning shaft 25 is rotated about the rotary axis A1.

The suction pump 22 operates on the basis of a command from the controller 80 and the suction valve 24 opens the flow path in the suction pipe 23 on the basis of a command from the controller 80. In response to this, air in the suction groove is drawn into the suction hole to create negative pressures lower than atmospheric pressure in the suction grooves. As a result, a center of a lower surface of the substrate W placed on the upper surface of the spinning base 21 is suctioned to the spinning base 21.

The substrate processing apparatus 10 includes a processing liquid supplier 30. The processing liquid supplier 30 is to supply the processing liquid to the upper surface Wf of the rotating substrate W. The processing liquid supplier 30 includes a nozzle 31, a nozzle mover 32, a pipe 33, branch pipes 34 and 35, and supply valves 36 and 37.

The nozzle 31 has an ejection port pointed downward. The nozzle mover 32 moves the nozzle 31 in a horizontal direction on the basis of a command from the controller 80. More specifically, the nozzle mover 32 moves the nozzle 31 between a position above the center of the upper surface Wf of the substrate W and a position spaced apart from the substrate W in the horizontal direction. For example, the nozzle mover 32 includes an arm supporting the nozzle 31, and a motor that rotates the arm within a horizontal plane. The nozzle mover 32 may include an actuator that moves the nozzle 31 in the vertical direction. The actuator includes an air cylinder or a hydraulic cylinder.

The pipe 33 is connected to the nozzle 31. The pipe 33 branches into the two branch pipes 34 and 35. A flow path in the branch pipe 34 is connected to a tank (not shown in the drawings) storing the developing liquid therein. The supply valve 36 is interposed in the branch pipe 34. The supply valve 36 opens and closes the flow path in the branch pipe 34 on the basis of a command from the controller 80. A flow path in the branch pipe 35 is connected to a tank (not shown in the drawings) storing the rinsing liquid therein. If the rinsing liquid is pure water, the flow path in the branch pipe 35 may be connected to a pure water source as a utility of the factory. The supply valve 37 opens and closes the flow path in the branch pipe 35 on the basis of a command from the controller 80.

When the supply valve 36 is opened and the supply valve 37 is closed on the basis of a command from the controller 80, the nozzle 31 ejects the developing liquid downward from ejection port. By supplying the developing liquid to the upper surface Wf of the substrate W in this way, the developing process is performed on the substrate W. Meanwhile, when the supply valve 37 is opened and the supply valve 36 is closed on the basis of a command from the controller 80, the nozzle 31 ejects the rinsing liquid downward from the ejection port. By ejecting the rinsing liquid to the upper surface Wf of the substrate W in this way, a rinsing process is performed on the substrate W.

The substrate processing apparatus 10 includes a cup unit 40. The cup unit 40 is a member for collecting the processing liquid shaken off from the substrate W during the developing process and the rinsing process. The cup unit 40 includes the lower cup 41, a guard 42, and a middle cup 43. The spinning shaft 25 and the cup unit 40 are arranged coaxially about the rotary axis A1.

The lower cup 41 is a container having a circular cylindrical shape with a closed bottom provided around and below the spinning base 21. More specifically, the lower cup 41 includes a bottom wall part 411, a side wall part 413, and an inner wall part 415. The bottom wall part 411 has a circular shape in a top view, and has a through hole formed at the center and penetrating the bottom wall part 411 in the vertical direction. The spinning shaft 25 is inserted in the through hole at the bottom wall part 411. The side wall part 413 has a circular cylindrical shape standing vertically from an outer peripheral edge of the bottom wall part 411. The inner wall part 415 has a circular cylindrical shape standing vertically from an inner peripheral edge of the bottom wall part 411.

The guard 42 receives the processing liquid having been discharged externally from the substrate W in a gas flow generated in response to the rotation of the substrate W. The guard 42 has a cylindrical shape tilting upward toward the internal side of the radial direction. The guard 42 is movable in the vertical direction with respect to the lower cup 41.

The guard 42 is mounted with a lifting/lowering part 421. On the basis of a command from the controller 80, the lifting/lowering part 421 moves the guard 42 up and down in the vertical direction between an upper position (a position indicated by alternate long and two short dashes lines) and a lower position (a position indicated by solid lines). The lifting/lowering part 421 includes a motor as a drive source, and a guide that guides movement of the guard 42 in the vertical direction. A linear motor mechanism or a ball screw mechanism is available as a drive mechanism of the lifting/lowering part 421, for example.

When the guard 42 is at the upper position, an upper end of the guard 42 is located above the position of the substrate W supported on the spinning base 21 (support position). When the guard 42 is at the lower position, the upper end of the guard 42 is located below the support position of the substrate W.

The middle cup 43 is located above the bottom wall part 411 of the lower cup 41. The middle cup 43 is a member having an annular shape in a top view. The middle cup 43 includes an upper wall part 431 and an outer wall part 433. The upper wall part 431 has an inner peripheral edge fixed to an outer surface of the inner wall part 415 of the lower cup 41. The upper wall part 431 tilts downward toward the external side of the radial direction, and has an arch shape as a whole. The outer wall part 433 has a cylindrical shape extending vertically downward from an outer peripheral edge of the upper wall part 431. A lower end of the upper wall part 431 is positioned above the bottom wall part 411 of the lower cup 41.

The substrate processing apparatus 10 includes a zoning plate 47 and a cylindrical part 48. The zoning plate 47 has a circular disk shape in a top view. The zoning plate 47 defines a processing space and a non-processing space in the substrate processing apparatus 10. A through hole is formed in the vertical direction at the center of the zoning plate 47. If the substrate W is to be processed with the processing liquid, the nozzle 31 supplies the processing liquid to the substrate W via the through hole at the zoning plate 47.

The cylindrical part 48 has a circular cylindrical shape extending downward from an outer edge of the zoning plate 47. The cylindrical part 48 has an inner diameter larger than an outer diameter of the upper end of the guard 42. The cylindrical part 48 is located into position in such a manner as to allow the upper end of the guard 42 to be inserted into the cylindrical part 48. Thus, in moving up the guard 42, it is possible to insert the upper end of the guard 42 into the cylindrical part 48 without causing contact with the cylindrical part 48.

The substrate processing apparatus 10 includes a gas flow distribution plate 50 (gas flow distribution member). The gas flow distribution plate 50 has a cylindrical shape (circular cylindrical shape or square cylindrical shape, for example). When viewed in the radial direction, the gas flow distribution plate 50 is arranged on the internal side with respect to the outer wall part 433 of the middle cup 43 and on the external side with respect to the inner wall part 415 of the lower cup 41. When viewed in the vertical direction, the gas flow distribution plate 50 is arranged between the bottom wall part 411 of the lower cup 41 and the upper wall part 431 of the middle cup 43. The gas flow distribution plate 50 stands upward from a bottom surface of the lower cup 41 (an upper surface of the bottom wall part 411) to an inner surface of the upper wall part 431 of the middle cup 43. Specifically, a lower end of the gas flow distribution plate 50 is in contact with the bottom wall part 411, and an upper end of the gas flow distribution plate 50 is in contact with the upper wall part 431 of the middle cup 43.

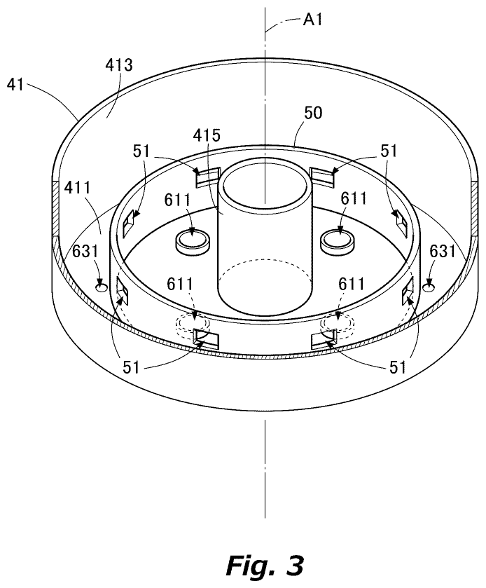

FIG. 3 is a perspective view showing the gas flow distribution plate 50 arranged in the lower cup 41. The upper part of the lower cup 41 is cut out from FIG. 3. The gas flow distribution plate 50 has a plurality of opening parts 51 arranged in the peripheral direction. Each opening part 51 is a through hole penetrating the gas flow distribution plate 50 in the radial direction. The shape of the opening part 51 is a substantially rectangular shape in a front view, for example. However, the shape of the opening part 51 is freely changeable. The length of the opening part 51 in the peripheral direction is shorter than the length of the gas flow distribution plate 50 in the peripheral direction (circumference). The opening parts 51 are arranged at a uniform angular interval in the peripheral direction. In this preferred embodiment, eight opening parts 51 are arranged at an interval of 45° (=360/8). However, it is not essential to arrange the opening parts 51 in a uniform angular interval.

As shown in FIGS. 2 and 3, each opening part 51 is separated upward from the bottom wall part 411 of the lower cup 41. The opening part 51 has a lower end separated upward from a lower end of the outer wall part 433 of the middle cup 43. Specifically, the lower end of each opening part 51 is separated upward from an annular clearance H between the bottom wall part 411 of the lower cup 41 and the outer wall part 433 of the middle cup 43.

The substrate processing apparatus 10 includes a plurality of exhaust pipes 61 and a plurality of drainage pipes 63. These exhaust pipes 61 guide an atmosphere in the chamber 11 to an exhaust device provided outside the chamber 11. The exhaust device includes a pump or a fan, for example. The exhaust device may be an exhaust source as a utility of the factory. The exhaust pipes 61 may merge into one pipe halfway through. As shown in FIG. 3, each exhaust pipe 61 is inserted in a corresponding through hole penetrating the bottom wall part 411 of the lower cup 41. An exhaust port 611 as an opening end of the exhaust pipe 61 is located above the bottom wall part 411 and is pointed vertically upward. When viewed in the radial direction, the exhaust port 611 is arranged on the internal side with respect to the gas flow distribution plate 50. The exhaust port 611 is arranged below the opening part 51 of the gas flow distribution plate 50. Specifically, in the vertical direction, the exhaust port 611 is located between the opening part 51 and the bottom wall part 411.

The exhaust ports 611 are arranged at a uniform angular interval in the peripheral direction. In this example, four exhaust pipes 61 are fixed to the bottom wall part 411. Four exhaust ports 611 are provided at the bottom wall part 411 at an interval of 90° (=360/4) in the peripheral direction. However, it is not essential to arrange the exhaust ports 611 in a uniform angular interval.

With the provision of the plurality of opening parts 51 on the gas flow distribution plate 50, it is possible to avoid exhaust concentration on the opening part 51 near the exhaust port 611. The opening parts 51 and the exhaust ports 611 are shifted from each other in order to prevent their positions (angles) from overlapping each other. In this example, while the eight opening parts 51 are arranged at positions of 0°, 45°, 90°, 135°, 180°, 225°, 270°, and 315°, the four exhaust ports 611 are arranged at positions of 22.5°, 112.5°, 202.5°, and 292.5°. By shifting the positions of the opening parts 51 and those of the exhaust ports 611 from each other in this way, this allows for the prevention of exhaust concentration on a particular opening part 51.

The drainage pipes 63 are connected to corresponding through holes provided in the bottom wall part 411 of the lower cup 41. When the substrate W is processed with the processing liquid, the processing liquid flowing from the guard 42 to the bottom wall part 411 of the lower cup 41 is guided by the drainage pipes 63 to a drainage device provided outside the chamber 11. The drainage device includes a pump for pumping the processing liquid under pressure, and a tank for storing the processing liquid.

A drainage port 631, which is an opening end of the drainage pipe 63 is located at the same height as or below the upper surface of the bottom wall part 411 (bottom surface). As viewed in the vertical direction, the drainage port 631 is located below the exhaust port 611 of the exhaust pipe 61. The drainage ports 631 are arranged at a uniform angular interval in the peripheral direction. In this example, two drainage pipes 63 are fixed to the bottom wall part 411. Two drainage ports 631 are provided at the bottom wall part 411 at an interval of 180° (=360/2). The upper surface of the bottom wall part 411 of the lower cup 41 may tilt downward as it approaches the drainage port 631. This allows the processing liquid to be guided to the drainage port 631.

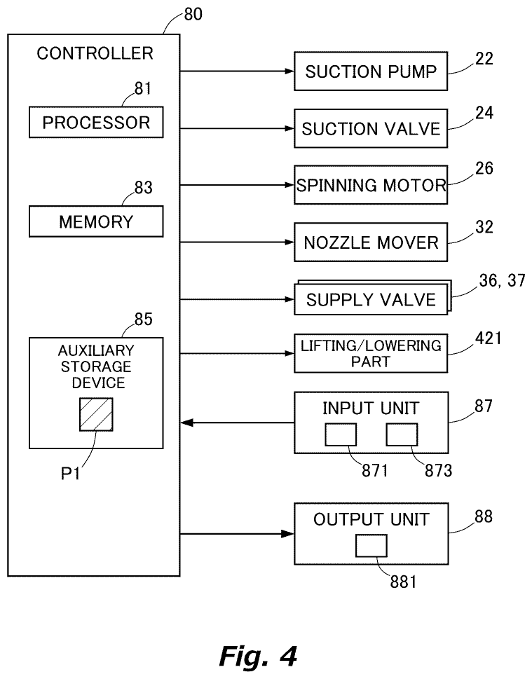

FIG. 4 is a control block diagram of the substrate processing apparatus 10. The controller 80 is a unit for controlling the operation of each part of the substrate processing apparatus 10. The controller 80 includes a processor 81, a memory 83, and an auxiliary storage device 85.

The processor 81 includes a central processing unit (CPU) or a micro processing unit (MPU). The processor 81 may include a general-purpose computing unit, a dedicated computing unit, a graphics processing unit (GPU), a neural network processing unit (NPU), or a quantum computer. The dedicated computing unit may include an application specific integrated circuit (ASIC), for example.

The memory 83 includes a main storage device. The main storage device is a semiconductor memory such as a random access memory (RAM), for example. The memory 83 may include a nonvolatile memory such as a read-only memory (ROM) for storing a program or data. The auxiliary storage device 85 is a solid state drive (SSD) or a hard disk drive (HDD), for example. The auxiliary storage device 85 may include a removable medium such as a USB memory.

The auxiliary storage device 85 stores a computer program P1. The computer program P1 includes a program for controlling the operation of the substrate processing apparatus 10. The processor 81 reads the computer program P1 from the auxiliary storage device 85 into the memory 83 and executes it, thereby controlling the operating elements of the substrate processing apparatus 10.

The controller 80 is electrically connected to an input unit 87 and an output unit 88. The input unit 87 inputs an instruction or data responsive to an operation by an operator to the controller 80. The input unit 87 includes a keyboard 871 and a mouse 873, for example. The input unit 87 may include a reader to read data from a removable medium. The output unit 88 includes a display 881 on which each type of information is displayed. The display 881 is a liquid crystal display or an organic electroluminescent (EL) display, for example. The input unit 87 may include a touch panel sensor laid on a display surface of the display 881. The output unit 88 may include a speaker, a printer, or a lamp.

The controller 80 is electrically connected to the suction pump 22, the suction valve 24, the spinning motor 26, the nozzle mover 32, the supply valves 36 and 37, and the lifting/lowering part 421, and processes the substrate W with the processing liquid by controlling these parts. More specifically, the controller 80 controls the suction pump 22 and the suction valve 24 to hold the substrate W horizontally on the spinning base 21 (chuck) after the substrate W is loaded into the chamber 11. Next, the controller 80 controls the lifting/lowering part 421 to locate the guard 42 at the upper position. The controller 80 further controls the nozzle mover 32 to locate the nozzle 31 at the position above the center of the upper surface Wf of the substrate W. Next, the controller 80 controls the spinning motor 26 to rotate the substrate W about the vertical rotary axis A1 passing through a center WC of the substrate W. In this state, the controller 80 controls the supply valves 36 and 37 to supply the processing liquid (developing liquid or rinsing liquid) to the rotating substrate W from the nozzle 31.

During implementation of the substrate process, the exhaust device performs exhaust via the exhaust port 611. By doing so, a gas flow toward the exhaust port 611 is generated in the cup unit 40. More specifically, the generated gas flow passes through between the guard 42 and the middle cup 43, passes through between the lower cup 41 and the middle cup 43, passes through the clearance H between the middle cup 43 and the lower cup 41, and passes through the plurality of opening parts 51 of the gas flow distribution plate 50 sequentially. A space on the external side of the radial direction with respect to the gas flow distribution plate 50 and a space on the internal side of the radial direction with respect to the gas flow distribution plate 50 communicate with each other only via the opening parts 51. Thus, when the exhaust is performed via the exhaust port 611, an atmosphere having passed through the clearance H is sucked into the exhaust port 611 only via the plurality of opening parts 51.

The processing liquid supplied to the substrate W from the nozzle 31 is scattered laterally by the rotation of the substrate W to collide with the guard 42. Mist generated by this collision passes through the clearance H between the lower cup 41 and the middle cup 43 to get into the middle cup 43. Due to its weight, the mist of the processing liquid cannot enter the opening part 51 and remains outside the gas flow distribution plate 50. Thus, the mist drops onto the bottom wall part 411 of the lower cup 41 and discharged from the drainage port 631. This configuration, with the gas flow distribution plate 50 provided in the middle cup 43, enables for effective gas-liquid separation within the middle cup 43.

Providing a gas-liquid separator to the drainage pipe 63 like in the conventional case causes size increase of the apparatus. In particular, providing a gas-liquid separator below the substrate processing apparatus 10 increases the height of the space for processing the substrate W in the substrate processing apparatus 10 in response to the size of the gas-liquid separator. This further increases the height position of a maintenance space or increases the height position of a pass line for transferring the substrate W. As a result, the gas flow distribution plate 50 is used in place of a gas-liquid separator. This allows for gas-liquid separation in a reduced space, enabling a more compact apparatus. Furthermore, it is possible to locate the maintenance space and the pass line at low height positions.

### <2. Modifications>

Although the preferred embodiment has been described above, the present invention is not limited to the above-described embodiment and can be modified in various ways.

For example, it is not essential to provide the plurality of opening parts 51 at the gas flow distribution plate 50 but the number of the opening parts 51 may be one. It is not essential to provide the plurality of exhaust ports 611 but the number of the exhaust ports 611 may be one. Multiple drainage ports 631 are not required, and a single drainage port 631 may be used.

While the substrate processing apparatus is configured to supply the developing liquid as the processing liquid in the above preferred embodiment, it may be configured to supply a different type of processing liquid (etching liquid, for example). Specifically, the present invention is applicable to a wide range of substrate processing techniques for processing a substrate by supplying a processing liquid to an upper surface of the substrate while rotating it.

In the above preferred embodiment, the opening part 51 is composed of a through hole provided at the gas flow distribution plate 50. Alternatively, the opening part 51 may comprise a cutout formed in the gas flow distribution plate 50, and another member for closing the cutout.

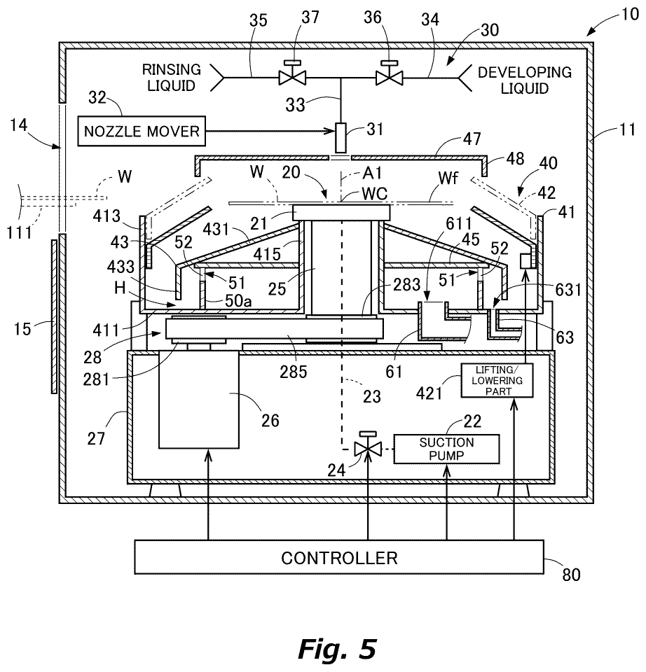

FIG. 5 is a schematic sectional view showing the configuration of a substrate processing apparatus 10 according to a modification. The substrate processing apparatus 10 according to the modification includes a partition plate 45 and a gas flow distribution plate 50a. The partition plate 45 is arranged inside the middle cup 43. The partition plate 45 has an annular shape extending in the radial direction from the inner wall part 415 of the lower cup 41 to an inner peripheral surface of the middle cup 43. The partition plate 45 partitions the interior of the middle cup 43 in the vertical direction into two spaces.

The gas flow distribution plate 50a is located between the bottom wall part 411 of the lower cup 41 and the partition plate 45. The gas flow distribution plate 50a includes a plurality of cutout parts 52 provided at the top thereof. The cutout parts 52 each have a shape recessed downward. The top of the gas flow distribution plate 50a except the cutout parts 52 is in contact with a lower surface of the partition plate 45, and the top of each cutout part 52 is closed by the partition plate 45. The respective tops of the cutout parts 52 are closed by the partition plate 45, thereby forming the plurality of opening parts 51.

According to the modification, it is also possible to make gas-liquid separation properly using the gas flow distribution plate 50a arranged in the middle cup 43. Thus, it is possible to make gas-liquid separation in a reduced space. Furthermore, even if the length of the gas flow distribution plate 50a in the vertical direction is short, providing the cutout part 52 at the top of the gas flow distribution plate 50a still makes it possible to set the highest possible position for the opening part 51. This enables effective gas-liquid separation. The partition plate 45 is optional. For example, the opening part 51 may be formed by contacting the top of the gas flow distribution plate 50a into contact with the upper wall part 431 of the middle cup 43, thereby closing the top of the cutout part 52 with the upper wall part 431.

While the invention has been shown and described in detail, the foregoing description is in all aspects illustrative and not restrictive. It is therefore understood that numerous modifications and variations can be devised without departing from the scope of the invention. The structures described in each preferred embodiment and modification described above can be consistently combined together or omitted as appropriate, without contradicting each other.

What is claimed is:

1. A substrate processing apparatus comprising:
a chuck that holds a substrate;
a spinning shaft mounted on said chuck;
a motor that rotates said spinning shaft about a rotary axis extending in a vertical direction;
a nozzle that supplies a processing liquid to the substrate held by said chuck;
a lower cup having a circular cylindrical shape with a closed bottom arranged around and below said chuck;
a middle cup having an annular shape located below said chuck and above a bottom of said lower cup; and
a gas flow distribution member having a cylindrical shape standing upward from the bottom of said lower cup toward said middle cup, wherein
said gas flow distribution member includes at least one opening part, and
said lower cup includes an exhaust port arranged on an internal side of a radial direction with respect to said gas flow distribution member, and a drainage port arranged on an external side of said radial direction with respect to said gas flow distribution member.

2. The substrate processing apparatus according to claim 1, wherein
said gas flow distribution member includes a plurality of said opening parts arranged in a peripheral direction.

3. The substrate processing apparatus according to claim 1, wherein
a clearance is formed between a lower end of said middle cup and a bottom surface of said lower cup, and
said opening part is located above the clearance.

4. The substrate processing apparatus according to claim 1, wherein
said middle cup includes a part tilting downward toward an external side of said radial direction.

5. The substrate processing apparatus according to claim 1, further comprising:
a base mounted with said motor and supporting said lower cup;
a drive pulley mounted on a drive shaft of said motor;
a driven pulley mounted on said spinning shaft; and
a drive belt stretched over said drive pulley and said driven pulley.
